(19) United States
(12) Patent Application Publication
(10) Pub. No.: US 2018/0012791 A1
(43) Pub. Date: Jan. 11, 2018

(54) INTERCONNECTS WITH INNER SACRIFICIAL SPACERS

(71) Applicant: GLOBALFOUNDRIES Inc., Grand Cayaman, KY (US)

(72) Inventors: Zhiguo Sun, Halfmoon, NY (US); Qiang Fang, Ballston Lake, NY (US); Suraj K. Patil, Ballston Lake, NY (US); Jiehui Shu, Clifton Park, NY (US)

(21) Appl. No.: 15/202,867

(22) Filed: Jul. 6, 2016

(51) Int. Cl. H01L 21/768; H01L 23/522; H01L 23/532

(52) U.S. Cl. CPC H01L 21/7682; H01L 23/5329; H01L 23/53238; H01L 21/76802; H01L 21/76879; H01L 21/76852; H01L 23/5226

(57) ABSTRACT

Interconnect structures and methods of forming such interconnect structures. A spacer is formed inside an opening in a dielectric layer. After the spacer is formed, a conductive plug is formed inside the opening in the dielectric layer. After the conductive plug is formed, the spacer is removed to define an air gap located inside the opening in the dielectric layer. The air gap is located between the conductive plug and the opening in the dielectric layer.

### BACKGROUND

The present invention relates to integrated circuits and semiconductor device fabrication and, more specifically, to interconnect structures for a chip and methods of forming such interconnect structures.

A back-end-of-line (BEOL) interconnect structure may be used to electrically connect device structures fabricated on a substrate by front-end-of-line (FEOL) processing. The BEOL interconnect structure may be formed using a dual damascene process in which via openings and trenches etching in a dielectric layer are simultaneously filled with metal to create a metallization level. In a via-first, trench-last dual damascene processing process in which a via opening is formed in a dielectric layer and then a trench is formed above the via opening, the via openings are unfilled during the etching process forming the trenches. In a single damascene process, the via openings and trenches are formed in different dielectric layers and filled separately with metal.

Improved interconnect structures for a chip and methods of forming such interconnect structures are needed.

### SUMMARY

According to an embodiment of the invention, an interconnect structure includes a dielectric layer including an opening, a conductive plug inside the opening in the dielectric layer, and an air gap inside the opening in the dielectric layer at a location between the conductive plug and the opening in the dielectric layer.

According to another embodiment of the invention, a method includes forming an opening in a dielectric layer, and forming a spacer inside the opening in the dielectric layer. After the spacer is formed, a conductive plug is formed inside the opening in the dielectric layer. After the conductive plug is formed, the spacer is removed to form an air gap inside the opening in the dielectric layer. The air gap is located between the conductive plug and the opening in the dielectric layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-6 are cross-sectional views of an interconnect structure at successive fabrication stages of a processing method in accordance with an embodiment of the invention.

### DETAILED DESCRIPTION

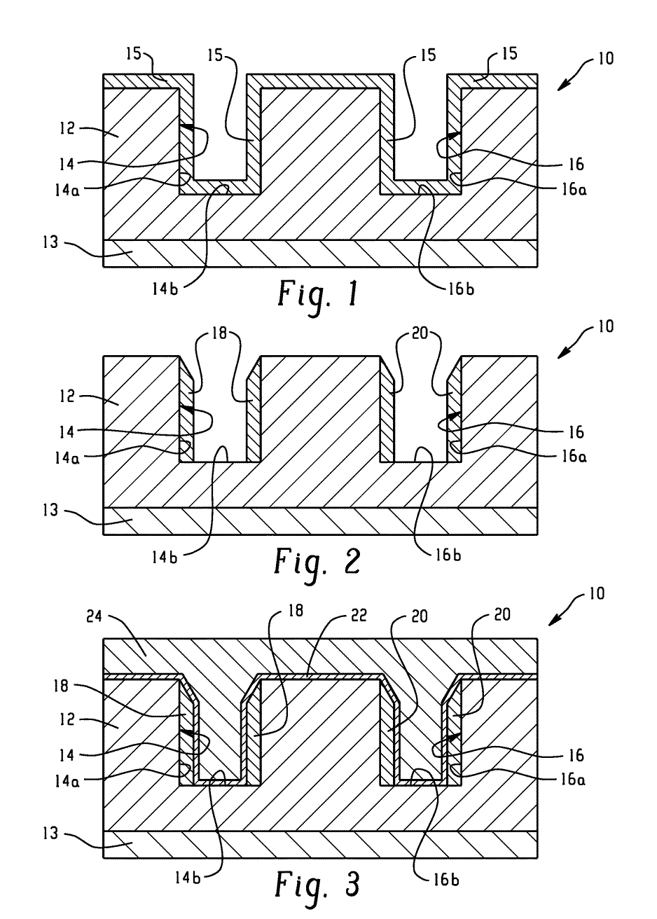

With reference to FIG. 1 and in accordance with an embodiment of the invention, a dielectric layer 12 is processed to form a metallization level 10 of a BEOL interconnect structure that is carried on a substrate 13, which may be a silicon wafer processed by front-end-of-line (FEOL) processing to form an integrated circuit. The dielectric layer 12 may be composed of an electrically-insulating dielectric material, such as a low-k dielectric material characterized by a relative permittivity or dielectric constant that is less than the dielectric constant of silicon dioxide (SiO₂), which is about 3.9. Candidate low-k dielectric materials for dielectric layer 12 include, but are not limited to, dense and porous organic low-k dielectrics, dense and porous inorganic low-k dielectric, such as organosilicate glasses, and combinations of such organic and inorganic dielectrics that are characterized by a dielectric constant of less than or equal to 3.0. In an alternative embodiment, the dielectric layer 12 may be composed of silicon dioxide deposited by chemical vapor deposition (CVD).

Openings, of which openings 14, 16 are representative, may be formed by photolithography and etching at selected locations distributed across the surface area of dielectric layer 12. Specifically, a resist layer may be applied, exposed to a pattern of radiation projected through a photomask, and developed to form a corresponding pattern of openings situated at the intended locations for the openings 14, 16 to be formed in the dielectric layer 12. The patterned resist layer is used as an etch mask for a dry etching process, such as a reactive-ion etching (REI), that removes portions of the dielectric layer 12 to form the openings 14, 16. The etching process may be conducted in a single etching step or multiple etching steps with different etch chemistries, and may open onto an underlying feature (not shown). The feature may be a conductive feature in an underlying dielectric layer that is aligned with the openings 14, 16. The opening 14 has sidewalls 14a, which may be vertical, that terminate at, and are connected by, a base surface 14b. Similarly, the opening 16 has sidewalls 16a, which may also be vertical, that terminate at, and are connected by, a base surface 16b proximate to the substrate 13.

A conformal layer 15 comprised of a given material that is chosen to selectively etch relative to the dielectric layer 12 is deposited that covers the sidewalls 14a, 16a and base surfaces 14b, 16b of the openings 14, 16. The conformal layer 15 has a layer thickness that is selected in conjunction with dimensions (e.g., a width dimension) of the openings 14, 16 in order to establish one or more dimensions for air gaps that are subsequently formed as described supra. The conformal layer 15 may also form in the field area on the top surface of the dielectric layer 12. The thickness of the conformal layer 15 is nominally the same at any location on the sidewalls 14a, 16a, base surfaces 14b, 16b, and the top surface of the dielectric layer 12 in the field area.

With reference to FIG. 2 in which like reference numerals refer to like features in FIG. 1 and at a subsequent fabrication stage, sacrificial spacers 18, 20 are formed from the conformal layer 15 and are located on the sidewalls 14a, 16a of the openings 14, 16. The sacrificial spacers 18, 20 have a set of given dimensions that is established, at least in part, by the layer thickness of the conformal layer 15. The sacrificial spacers 18, 20 may be formed by shaping the material of the conformal layer 15 with an etching process, such as reactive ion etching, that preferentially removes the material from horizontal surfaces, such as the top surface of the dielectric layer 12 and the base surfaces 14b, 16b of the openings 14, 16. The sacrificial spacers 18 extend from the base surface 14b of the opening 14 to the top surface of the dielectric layer 12. The sacrificial spacers 20 also extend from the base surface 16b of the opening 16 to the top surface of the dielectric layer 12. The sacrificial spacers 18, 20 are not present in the final device construction.

As mentioned infra, the material constituting the conformal layer 15 and, thus, the sacrificial spacers 18, 20 is selected to etch selectively to (i.e., at a higher etch rate than) the material of the dielectric layer 12 for ease of removal. In an embodiment, the conformal layer 15 and sacrificial spacers 18 may be constituted by a dielectric material formed from a layer of the dielectric material deposited by, for example, CVD. If the constituent dielectric material is specifically silicon nitride (Si₃N₄), the selective removal may be accomplished using, for example, hot phosphoric acid (H₂SO₄). If the constituent dielectric material is specifically silicon dioxide (SiO₂), the selective removal may be accomplished using, for example, diluted hydrofluoric acid (HF). If the constituent dielectric material is specifically phosphorus silicon glass (PSG), the selective removal may be accomplished using, for example, diluted hydrofluoric acid (HF).

In other embodiments, the conformal layer 15 and sacrificial spacers 18, 20 may be comprised of other types of materials, such as titanium nitride that can be selectively removed using, for example, a post etch residue remover (e.g., EKC) or amorphous silicon that can be selectively removed using, for example, tetramethylammonium hydroxide (TMAH).

With reference to FIG. 3 in which like reference numerals refer to like features in FIG. 2 and at a subsequent fabrication stage, a barrier/liner layer 22 of a given thickness is deposited on the sidewalls 14a, 16a and the base of the openings 14, 16 and also in the field area on the top surface of the dielectric layer 12. The barrier/liner layer 22 may be comprised of ruthenium (Ru), titanium (Ti), titanium nitride (TiN), tantalum (Ta), tantalum nitride (TaN), or a multilayer combination of these materials (e.g., a TaN/Ta bilayer) deposited by physical vapor deposition (PVD) with, for example, a sputtering process. A seed layer (not shown) may be formed on the sidewalls 14a, 16a of the openings 14, 16 and covers the barrier/liner layer 22. The seed layer may be comprised of copper (Cu), such as elemental Cu or co-deposited chromium-copper (Cr—Cu), applied using, for example, PVD.

After the deposition of the seed layer, a thicker conductor or metal layer 24 comprised of a low-resistivity metal, such as copper (Cu), may be deposited using a deposition process, such as electroplating or another electrochemical plating process, different than the deposition process used to deposit the seed layer. The seed layer may be required to carry the electrical current needed to initiate an electroplating process forming the metal layer 24 and may be subsumed into the metal layer 24. Respective residual portions of the seed layer and metal layer 24 are located inside the openings 14, 16. Alternatively, the metal layer 24 may be deposited with an electroless deposition process, which would permit the seed layer to be omitted.

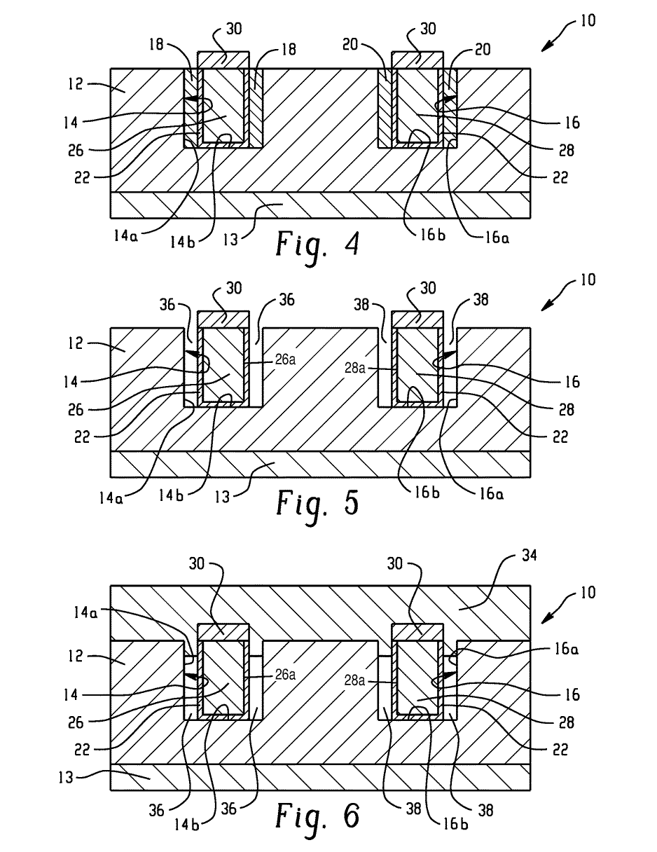

With reference to FIG. 4 in which like reference numerals refer to like features in FIG. 3 and at a subsequent fabrication stage, the metal layer 24 and the barrier/liner layer 22 are removed from the field area on the top surface of dielectric layer 12 by planarization, such as with one or more chemical mechanical polishing (CMP) processes. Material removal during a chemical mechanical polishing process combines abrasion and an etching effect that polishes the targeted material at the submicron level. Each chemical mechanical polishing process may be conducted with a commercial tool using standard polishing pads and slurries selected to polish the targeted material. Conductive or metal plugs 26, 28 comprised of the material originating from the metal layer 24 are retained inside the openings 14, 16. Each of the metal plugs 26, 28 is surrounded by one of the sacrificial spacers 18, 20. An upper surface of the sacrificial spacers 18, 20 is revealed following the chemical mechanical polishing process, which is carefully controlled to reveal the sacrificial spacers 18, 20.

A metal cap 30 is formed on the top surface of each metal plugs 26, 28 by selective deposition with, for example, CVD, which in this instance entails inducing a chemical reaction between a metal precursor and a co-reactant gas in the vicinity of the top surfaces of the metal plugs 26, 28. A solid reaction product is selectively deposited to form the metal plugs 26, 28. However, the reaction product does not form on the top surface of the dielectric layer 12 adjacent to the metal caps 30. The deposition conditions may be selected to provide a thin film that is highly conductive (i.e., low electrical resistance) and that exhibits good adhesion to cobalt without depositing on dielectric surfaces. In particular, the conductor in the metal caps 30 may be composed of ruthenium (Ru), a ruthenium-containing material (e.g., ruthenium oxide (RuOₓ)), cobalt (Co), or a cobalt-containing material (e.g., cobalt tungsten phosphide (CoWP)), deposited by low-temperature CVD. The metal caps 30 function to protect the top surfaces of the metal plugs 26, 28 during subsequent cleaning and etching processes against erosion or damage.

With reference to FIG. 5 in which like reference numerals refer to like features in FIG. 4 and at a subsequent fabrication stage, the sacrificial spacers 18, 20 may be removed by an etching process that removes the material constituting the sacrificial spacers 18, 20 selective to (i.e., at a higher etch rate than) the materials of the dielectric layer 12 and the metal caps 30. In an embodiment in which the sacrificial spacers 18, 20 are composed of silicon nitride (Si₃N₄), the etching process may be a wet chemical etching using hot phosphoric acid (H₃PO₄), or may be removed by a dry etching process with a fluorine-based chemistry. Other etchant chemistries, as described infra, may be applied for removal if the sacrificial spacers 18, 20 are composed of a different material.

The spaces vacated by the removed sacrificial spacers 18, 20 define air gaps 36, 38 that are unfilled by solid material. The air gaps 36, 38, which replace the sacrificial spacers 18, 20, may have one or more dimensions that are nominally equal to the dimensions of the sacrificial spacers 18, 20 following the polishing process that removes the metal layer 24 from the field area on the top surface of the dielectric layer 12. In an embodiment, the width of the air gaps 36, 38 is equal to the layer thickness of the sacrificial spacers 18, 20. The air gap 36 is located between the sidewall 14a of the opening 14 and the nearest exterior sidewall 26a of the metal plug 26 across the spatial gap created by the air gap 36. Similarly, the air gap 38 is located between the sidewall 16a of the opening 16 and the nearest exterior sidewall 28a of the metal plug 28 across the spatial gap created by the air gap 38. The metal plugs 26, 28 are located between the different sections of the respective associated air gaps 32, 38. The air gap 36 extends vertically from one end at the base surface 14b to an open end at the top surface of the dielectric layer 12. Similarly, the air gap 38 extends vertically from one end at the base surface 16b to an open end at the top surface of the dielectric layer 12. The air gap 36 and the metal plug 26 are coextensive with the base surface 14b of the opening 14 in the dielectric layer 12, and the metal plug 26 is coplanar with a portion of the perimeter of the air gap 36 at the base surface 14b. The air gap 38 and the metal plug 28 are coextensive with the base surface 16b of the opening 16 in the dielectric layer 12, and the metal plug 28 is coplanar with a portion of the perimeter of the air gap 38 at the base surface 16b.

The metal plug 26 is located between different sections of the associated air gap 32. Similarly, the metal plug 28 is located between the different sections of the associated air gap 38. In an embodiment, the air gaps 36, 38 may each extend about the perimeter of the associated one of the metal plugs 26, 28 such that the air gaps 36, 38 represent continuous open spaces that surround the respective metal plugs 26, 28.

The air gaps 36, 38 may have a dielectric constant (e.g., relative permittivity) of near unity (i.e., about 1.0), which reflects that the air gaps 36, 38 are filled by air at or near atmospheric pressure, are filled by another gas at or near atmospheric pressure, or contain air or gas at a sub-atmospheric pressure (e.g., a partial vacuum). The dielectric constant is given by the ratio of the permittivity of a substance to the permittivity of a vacuum. Because the air gaps 36, 38 have a dielectric constant that is less than the dielectric constant of the material constituting the dielectric layer 12, the composite dielectric constant of the dielectric material proximate to each of the metal plugs 26, 28 is reduced.

A liner (not shown) may be formed that covers the dielectric material of dielectric layer 12 and the metal plugs 26, 28 that border the air gaps 36, 38. The liner may be comprised of an electrical insulator with a dielectric constant characteristic of a dielectric material, such as a high temperature oxide (HTO) deposited using a rapid thermal process (RTP).

With reference to FIG. 6 in which like reference numerals refer to like features in FIG. 5 and at a subsequent fabrication stage, a dielectric layer 34 may be deposited on dielectric layer 12. The dielectric layer 34 functions as a capping layer to close the air gaps 36, 38 and seal the spaces formerly occupied by the sacrificial spacers 18, 20. Candidate inorganic dielectric materials for the dielectric layer 34 may include, but are not limited to, silicon carbon nitride (SiCN), hydrogen-enriched silicon oxycarbide (SiCOH), and combinations of these and other dielectric materials. In the representative embodiment, portions of the dielectric layer 34 may penetrate into a respective upper portion of the air gaps 36, 38 so that the volume of the air gaps 36, 38 is slightly reduced relative to the height established after the sacrificial spacers 18, 20 are removed. Alternatively, the dielectric layer 34 may merely cover and occlude the previously open end of the air gaps 36, 38 such that the volume of the air gaps 36, 38 is not reduced.

Because the sacrificial spacers 18, 20 narrow the openings 14, 16, a larger process margin exists for the lithography process used to form the openings 14, 16. In other words, the openings 14, 16 may be formed in the dielectric layer 12 with larger dimensions and subsequently narrowed with the formation of the sacrificial spacers 18, 20 before the metal plugs 26, 28 are formed. The dimensions of the metal plugs 26, 28 are less than the dimensions of the openings 14, 16 because of the presence of the sacrificial spacers 18, 20. The air gaps 36, 38, which have a relative permittivity that is less than the relative permittivity of the dielectric layer 12, operate to reduce the capacitance of the metallization level 10. The profile of the openings 14, 16 with the inner sacrificial spacers 18 may be friendly to deposition of the barrier/liner layer 22 and the plating used to form the metal layer 24, which may reduce the incidence of metal (e.g., copper) voiding in the metal plugs 26, 28. The volume of the air gaps 36, 38 is predictable and controllable at least in part through control over the dimensions of the sacrificial spacers 18.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refers to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature may be “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1-7. (canceled)

8. A method comprising:
forming a first dielectric layer;
forming an opening in the first dielectric layer;
forming a spacer inside the opening in the first dielectric layer;
forming a conductive plug inside the opening in the first dielectric layer;
forming a protective cap on the conductive plug;
after the conductive plug and protective cap are formed, removing the spacer by an etching process to form an air gap inside the opening in the first dielectric layer at a location between the conductive plug and the opening in the first dielectric layer; and
after the spacer is removed, forming a dielectric liner on a sidewall of the first dielectric layer bordering the air gap.

9. The method of claim 8 wherein removing the spacer to form the air gap located inside the opening in the first dielectric layer at the location between the conductive plug and the opening in the first dielectric layer comprises:
selectively etching the spacer relative to the first dielectric layer to remove the spacer and form the air gap.

10. The method of claim 9 wherein the first dielectric layer is comprised of a low-k dielectric material, the spacer is comprised of a dielectric material, and the dielectric material of the spacer etches selectively to the low-k dielectric material.

11. The method of claim 9 wherein the first dielectric layer is comprised of a low-k dielectric material, the spacer is comprised of silicon nitride, and the spacer is selectively etched using a solution comprised of phosphoric acid.

12. The method of claim 9 wherein the first dielectric layer is comprised of a low-k dielectric material, the spacer is comprised of silicon dioxide, and the spacer is etched using a solution comprised of hydrofluoric acid.

13. The method of claim 9 wherein the first dielectric layer is comprised of a low-k dielectric material, the spacer is comprised of phosphorus silicon glass, and the spacer is etched using a solution comprised of hydrofluoric acid.

14. The method of claim 9 wherein the first dielectric layer is comprised of a low-k dielectric material, the spacer is comprised of titanium nitride, and the spacer is etched using a solution comprised of post etch residue remover.

15. The method of claim 9 wherein the first dielectric layer is comprised of a low-k dielectric material, the spacer is comprised of amorphous silicon, and the spacer is etched using a solution comprised of Tetramethylammonium Hydroxide.

16. (canceled)

17. The method of claim 8 further comprising:
forming a second dielectric layer on the first dielectric layer,
wherein the second dielectric layer caps the opening to close the air gap.

18. The method of claim 8 wherein the first dielectric layer is comprised of a first dielectric material, the spacer is comprised of a second dielectric material, and forming the spacer inside the opening in the first dielectric layer comprises:
selecting the second dielectric material to be removed by etching selectively to the first dielectric material.

19. The method of claim 8 wherein forming the conductive plug inside the opening in the first dielectric layer comprises:
applying a metal layer that fills a portion of the opening not filled by the spacer; and
polishing the metal layer to reveal the spacer and form the conductive plug inside the opening.

20. (canceled)

21. The method of claim 8 wherein the dielectric liner is formed on a sidewall of the metal plug bordering the air gap, and the sidewall of the conductive plug is separated from the sidewall of the first dielectric layer by the air gap.

22. The method of claim 8 wherein the air gap has at least one dimension equal to a dimension of the sacrificial spacer removed from the opening.

23. The method of claim 8 wherein the air gap has a width equal to a thickness of the sacrificial spacer removed from the opening.

24. The method of claim 8 wherein the location of the air gap is laterally between a sidewall of the conductive plug and the sidewall of the first dielectric layer, and the sidewall of the first dielectric layer is separated from the sidewall of the conductive plug by the air gap.

25. The method of claim 24 wherein the sidewall of the conductive plug is an exterior sidewall that is closest in distance to the sidewall of the first dielectric layer.

26. The method of claim 24 wherein the opening extends in the first dielectric layer to a base surface, the sidewall of the first dielectric layer intersects the base surface, and the conductive plug and the air gap are coextensive with the base surface.
